(19) United States
(12) Patent Application Publication
(10) Pub. No.: US 2024/0337492 A1
(43) Pub. Date: Oct. 10, 2024

(54) Circuit Device and Physical Quantity Detection Device

(71) Applicant: SEIKO EPSON CORPORATION, Tokyo (JP)

(72) Inventor: Hideo HANEDA, Shiojiri (JP)

(21) Appl. No.: 18/626,438

(22) Filed: Apr. 4, 2024

(30) Foreign Application Priority Data
Apr. 6, 2023 (JP) 2023-061918

(51) Int. Cl. G01C 19/5776; G01C 19/00

(52) U.S. Cl. CPC G01C 19/5776; G01C 19/005

(57) ABSTRACT

A circuit device includes a drive circuit configured to drive a physical quantity transducer, a phase-locked loop circuit configured to generate a digital sinusoidal wave signal phase-locked to a drive clock signal from the drive circuit, an analog-to-digital (A/D) conversion circuit configured to perform A/D conversion of a detection signal of the physical quantity transducer, and a mixer configured to perform a multiplication between the digital detection signal after the A/D conversion and the digital sinusoidal wave signal. The phase-locked loop circuit is configured to perform a phase comparison between the drive clock signal and the digital sinusoidal wave signal or a digital phase signal to generate the digital sinusoidal wave signal phase-locked to the drive clock signal.

The present application is based on, and claims priority from JP Application Serial Number 2023-061918, filed Apr. 6, 2023, the disclosure of which is hereby incorporated by reference herein in its entirety.

### BACKGROUND

### 1. Technical Field

The present disclosure relates to a circuit device, a physical quantity detection device, and so on.

### 2. Related Art

A known physical quantity detection device detects a physical quantity based on a detection signal from a physical quantity transducer. In the physical quantity detection device, the physical quantity transducer is driven by a drive circuit and a detection circuit detects a physical quantity based on a detection signal from the physical quantity transducer. In addition, in detecting a physical quantity, synchronous detection is performed. For example, WO2015/072090 discloses a technique of generating a sine wave digital signal based on a signal the frequency of which is obtained by multiplying the frequency of a signal from the drive circuit by a multiplier to detect a physical quantity.

In the technique of WO2015/072090, an analog multiplier is provided in order to multiply the frequency of a signal from the drive circuit. However, such an analog multiplier has a large circuit area and large power consumption and therefore inhibits a reduction in the area and a decrease in the power consumption of a circuit device.

### SUMMARY

According to an aspect of the present disclosure, a circuit device includes a drive circuit configured to drive a physical quantity transducer, a phase-locked loop circuit configured to generate a digital sinusoidal wave signal phase-locked to a drive clock signal from the drive circuit, an analog-to-digital (A/D) conversion circuit configured to perform A/D conversion of a detection signal of the physical quantity transducer, and a mixer configured to perform a multiplication between the digital detection signal after the A/D conversion and the digital sinusoidal wave signal. The phase-locked loop circuit is configured to perform a phase comparison between the drive clock signal and the digital sinusoidal wave signal or a digital phase signal of the digital sinusoidal wave signal to generate the digital sinusoidal wave signal phase-locked to the drive clock signal.

In addition, according to another aspect of the present disclosure, a physical quantity detection device includes the circuit device described above and the physical quantity transducer.

### BRIEF DESCRIPTION OF THE DRAWINGS

FIG. 1 illustrates an exemplary configuration of a physical quantity detection device including a circuit device in the present embodiment.

FIG. 2 illustrates a detailed exemplary configuration of the physical quantity detection device including the circuit device in the present embodiment.

FIG. 3 illustrates an exemplary configuration of a phase-locked loop circuit.

FIG. 4 illustrates phase locking between a drive clock signal and a digital sinusoidal wave signal.

FIG. 5 illustrates phase locking between a drive clock signal and a digital sinusoidal wave signal.

FIG. 6 illustrates an exemplary configuration of the phase-locked loop circuit.

FIG. 7 illustrates a detailed exemplary configuration of the phase-locked loop circuit.

FIG. 8 illustrates a detailed exemplary configuration of the phase-locked loop circuit.

FIG. 9 illustrates a detailed exemplary configuration of the phase-locked loop circuit.

FIG. 10 is an exemplary configuration of a continuous-time delta-sigma A/D conversion circuit.

FIG. 11 is a block diagram illustrating a relationship between an operating clock frequency of the phase-locked loop circuit and a data output frequency of the A/D conversion circuit.

### DESCRIPTION OF EMBODIMENTS

The present embodiment will be described below. The present embodiment described below does not unduly limit the content of appended claims. In addition, all of the configurations described in the present embodiment are not necessarily indispensable constituent elements.

### 1. Circuit Device, Physical Quantity Detection Device

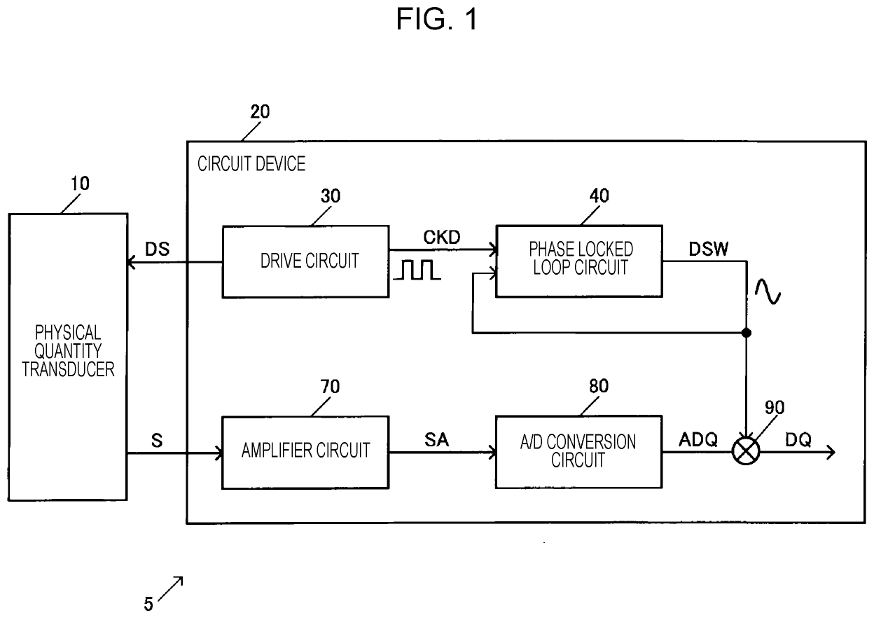

FIG. 1 illustrates an exemplary configuration of a physical quantity detection device 5 including a circuit device 20 in the present embodiment. The physical quantity detection device 5, which is a sensor device, includes a physical quantity transducer 10 and the circuit device 20.

The physical quantity transducer 10 is an element for detecting a physical quantity. The physical quantity transducer 10, which is a sensor element that detects a physical quantity, is, by way of example, a vibrator. When the physical quantity transducer 10 is a vibrator, the physical quantity transducer 10 includes a vibrator element and detects a physical quantity by using the vibrations of the vibrator element. When, for example, the physical quantity transducer 10 is a gyroscope sensor element, an angular velocity is detected as a physical quantity. Examples of the gyroscope sensor element include a sensor element including a piezoelectric vibrator element formed of a thin sheet of a piezoelectric material such as quartz crystal. Specifically, the gyroscope sensor element is a sensor element including a double T-shaped, tuning fork-type, H-shaped, or other vibrator element formed of a substrate of quartz crystal such as Z-cut quartz crystal. Alternatively, a micro-electromechanical systems (MEMS) sensor element may be used as the gyroscope sensor element. The physical quantity detected by the physical quantity transducer 10 may be a physical quantity other than angular velocity, such as acceleration, angular acceleration, velocity, movement distance, or pressure.

The circuit device 20 is, for example, a semiconductor circuit device and is, by way of example, a circuit device called Integrated Circuit (IC). The circuit device 20 may be referred to as a physical quantity detection circuit. As illustrated in FIG. 1, the circuit device 20 includes a drive circuit 30, a phase-locked loop circuit 40, an analog-to-digital (A/D) conversion circuit 80, and a mixer 90. The circuit device 20 may also include an amplifier circuit 70.

The drive circuit 30 is a circuit that drives the physical quantity transducer 10. For example, the drive circuit 30 drives the physical quantity transducer 10 by outputting a drive signal DS to the physical quantity transducer 10. When, for example, the physical quantity transducer 10 includes a vibrator element, driving is performed with the drive signal DS from the drive circuit 30 to cause the vibrator element to vibrate. The drive signal DS may be a square wave signal or a sinusoidal wave signal. Using a gyroscope sensor element as an example, driving of the drive circuit 30 causes the vibrator element to vibrate to detect the Coriolis force, thereby detecting an angular velocity.

The phase-locked loop circuit 40 is a circuit of generating a sinusoidal wave signal DSW in synchronization with a drive clock signal CKD. For example, the phase-locked loop circuit 40 generates the digital sinusoidal wave signal DSW phase-locked to the drive clock signal CKD from the drive circuit 30. The drive clock signal CKD is a square wave signal and is a clock signal at a given drive frequency. When, for example, the vibrator element of the physical quantity transducer 10 is caused to vibrate by driving of the drive circuit 30, the drive clock signal CKD is a clock signal at the frequency of the vibrations. The drive clock signal CKD may be referred to as a synchronization signal. Then, the phase-locked loop circuit 40 generates the digital sinusoidal wave signal DSW phase-locked to the drive clock signal CKD from the drive circuit 30. Phase locking is performed, by way of example, such that the edge timing such as a rising edge or a falling edge of the drive clock signal CKD matches the zero-crossing timing of the sinusoidal wave signal DSW. When phase adjustment is performed as described later, phase locking is performed such that a given phase difference is produced between the edge timing of the drive clock signal CKD and the zero-crossing timing of the sinusoidal wave signal DSW.

The amplifier circuit 70 receives a detection signal S from the physical quantity transducer 10 and performs an operation of amplifying the detection signal S. For example, the amplifier circuit 70 performs Q/V conversion, which is charge-to-voltage conversion, gain adjustment, and so on of the detection signal S. Then, the amplifier circuit 70 outputs an amplified detection signal SA.

The A/D conversion circuit 80 is a circuit that performs A/D conversion of a detection signal of the physical quantity transducer 10. In the example in FIG. 1, the amplifier circuit 70 is provided at the preceding stage of the A/D conversion circuit 80, and the A/D conversion circuit 80 performs A/D conversion of the detection signal SA that has been amplified by the amplifier circuit 70. In such a manner, the A/D conversion circuit 80 performs A/D conversion of the detection signal SA of the physical quantity transducer 10 to output a digital detection signal ADQ. As the A/D conversion circuit 80, circuits of various A/D conversion types, such as a delta-sigma (ΔΣ) type and a successive approximation resister (SAR) type, may be used.

The mixer 90 performs a multiplication between the digital detection signal ADQ after A/D conversion and the digital sinusoidal wave signal DSW. Then, the mixer 90 outputs a digital output signal DQ. The mixer 90 is a multiplication circuit that performs a multiplication between the digital detection signal ADQ and the digital sinusoidal wave signal DSW, and may be referred to as a detection circuit that detects a desired signal. For example, when the A/D conversion circuit 80 is an A/D conversion circuit with a multi-bit output, the multiplication of the mixer 90 may be performed by using a multi-bit multiplexer. Alternatively, when the A/D conversion circuit 80 is an A/D conversion circuit with a one-bit output, such as a ΔE A/D conversion circuit, the mixer 90 is implemented, for example, with a circuit that changes or switches the sign.

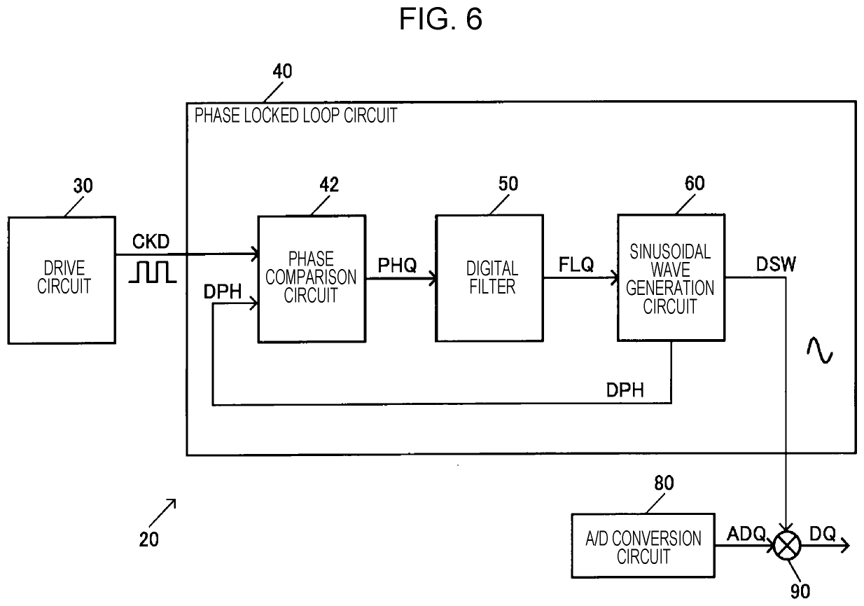

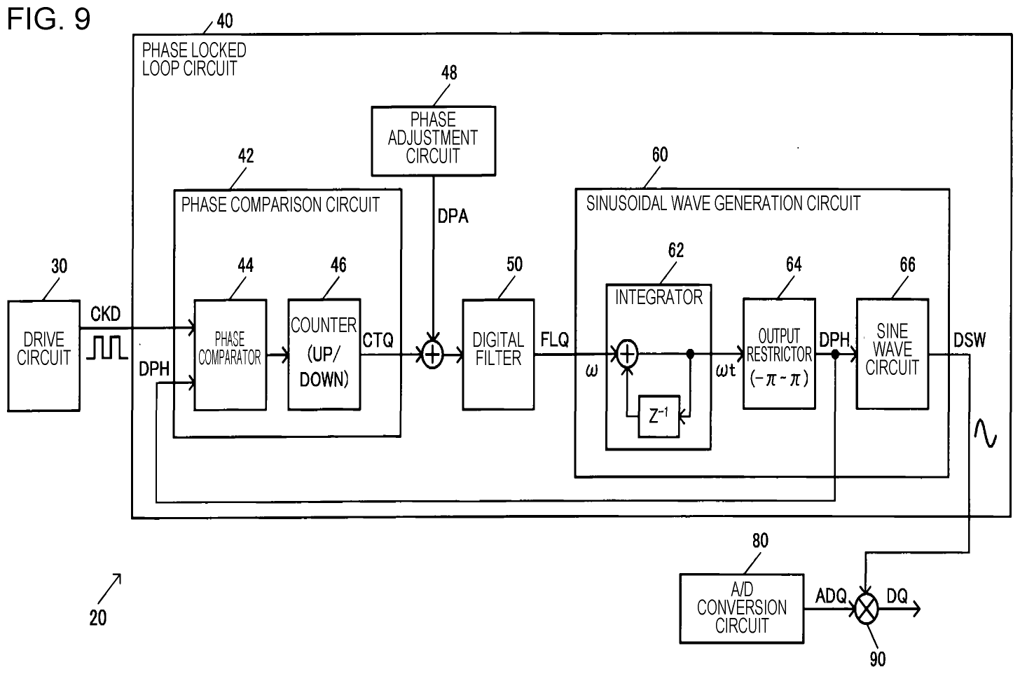

Then, the phase-locked loop circuit 40 performs a phase comparison between the drive clock signal CKD and the digital sinusoidal wave signal DSW to generate the digital sinusoidal wave signal DSW phase-locked to the drive clock signal CKD. Alternatively, as illustrated in FIG. 6 and FIG. 9 described later, the phase-locked loop circuit 40 performs a phase comparison between the drive clock signal CKD and a digital phase signal DPH to generate the digital sinusoidal wave signal DSW phase-locked to the drive clock signal CKD. The digital phase signal DPH is a signal representing the phase of the digital sinusoidal wave signal DSW. Hereafter, for brevity of description, an illustrative example in which the digital sinusoidal wave signal DSW is phase-locked to the drive clock signal CKD will be mainly described; however, the digital sinusoidal wave signal DSW in such a description may be replaced by the digital phase signal DPH.

For example, the digital sinusoidal wave signal DSW is a digital data signal, and the phase-locked loop circuit 40 samples digital values, which are the digital data of the sinusoidal wave signal DSW, for example, at a predetermined timing corresponding to the edge timing of the drive clock signal CKD. Then, the phase-locked loop circuit 40 generates the digital sinusoidal wave signal DSW phase-locked to the drive clock signal CKD by performing digital processing using the sampled digital values.

Then, the mixer 90 performs a multiplication between the digital detection signal ADQ, which is an A/D converted signal corresponding to the detection signal S of the physical quantity transducer 10, and the digital sinusoidal wave signal DSW. Thereby, a desired signal, which is a physical quantity signal such as an angular velocity signal, included in the detection signal S is detected.

For example, in response to the physical quantity transducer 10 being driven by the drive circuit 30, with a carrier wave having a frequency corresponding to the drive frequency of the drive circuit 30, the detection signal S in which the physical quantity signal is carried as the desired signal is output from the physical quantity transducer 10. Then, the digital detection signal ADQ corresponding to the detection signal S is output from the A/D conversion circuit 80. Then, with the mixer 90, a multiplication between the digital detection signal ADQ and the digital sinusoidal wave signal DSW phase-locked to the drive clock signal CKD is performed, which enables the desired signal to be detected from the detection signal S. That is, synchronous detection of the desired signal is achieved.

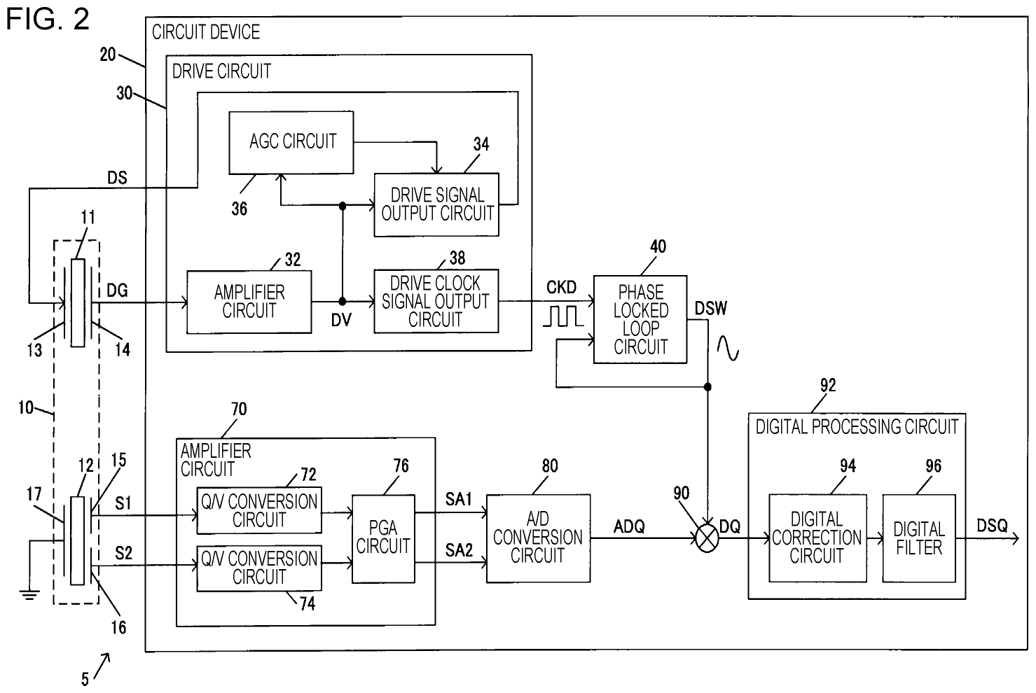

FIG. 2 illustrates a detailed exemplary configuration of the physical quantity detection device 5 including the circuit device 20 in the present embodiment. The configuration of the physical quantity detection device 5 including the circuit device 20 is not limited to the configuration in FIG. 2 and may be implemented as various modifications, such as omitting some of the components in the configuration, adding other components, and replacing some of the components with other components.

The physical quantity transducer 10, which is a sensor element, includes vibrator elements 11 and 12, drive electrodes 13 and 14, detection electrodes 15 and 16, and a ground electrode 17. Each of the vibrator elements 11 and 12 is, for example, a piezoelectric vibrator element formed of a thin sheet of a piezoelectric material such as quartz crystal. Specifically, each of the vibrator elements 11 and 12 is a vibrator element formed of a Z-cut quartz crystal substrate. The piezoelectric material for the vibrator elements 11 and 12 may be a material other than quartz crystal, such as ceramic or silicon.

The drive signal DS from the drive circuit 30 is supplied to the drive electrode 13, thereby causing the vibrator element 11 for driving to vibrate. Then, a feedback signal DG from the drive electrode 14 is input to the drive circuit 30. For example, the feedback signal DG due to vibration of the vibrator element 11 is input to the drive circuit 30. Then, the vibration of the vibrator element 11 for driving causes the vibrator element 12 for detection to vibrate, and electric charges produced by this vibration are input as the detection signals S1 and S2 from the detection electrodes 15 and 16 to the amplifier circuit 70. Here, the ground electrode 17 is set to GND, which is a ground potential. The circuit device 20 detects physical quantities, such as angular velocities corresponding to the detection signals S1 and S2, based on the detection signals S1 and S2.

The drive circuit 30 includes an amplifier circuit 32, a drive signal output circuit 34, an automatic gain control (AGC) circuit 36, and a drive clock signal output circuit 38.

The amplifier circuit 32 amplifies the feedback signal DG from the physical quantity transducer 10. For example, the amplifier circuit 32 converts the feedback signal DG current of current from the physical quantity transducer 10 to the signal DV of voltage and outputs the signal DV. The amplifier circuit 32 may be implemented with an operational amplifier, a resistor feedback component, a feedback capacitor, and so on.

The drive signal output circuit 34 outputs the drive signal DS based on the signal DV that has been amplified by the amplifier circuit 32. For example, when the drive signal output circuit 34 outputs the drive signal DS with a square wave, the drive signal output circuit 34 may be implemented, for example, with a comparator. The drive signal output circuit 34 may output the drive signal DS with a sinusoidal wave.

The AGC circuit 36, which is a gain control circuit, outputs a control voltage to the drive signal output circuit 34 to control the amplitude of the drive signal DS. Specifically, the AGC circuit 36 monitors the signal DV to control the gain of the oscillation loop. For example, in the drive circuit 30, in order to maintain the sensor sensitivity constant, the amplitude of a drive voltage supplied to the physical quantity transducer 10 is desired to be maintained constant. Therefore, the AGC circuit 36 for automatic adjustment of the gain is provided in the oscillation loop of the drive vibration system. The AGC circuit 36 automatically and flexibly adjusts the gain so that the feedback signal DG from the physical quantity transducer 10 has a constant amplitude. The AGC circuit 36 may be implemented with a full-wave rectifier that provides a full-wave rectification of the signal DV of the amplifier circuit 32, an integrator that performs an integration of an output signal of the full-wave rectifier, and so on.

The drive clock signal output circuit 38 receives the signal DV that has been amplified by the amplifier circuit 32 and outputs the drive clock signal CKD. For example, the drive clock signal output circuit 38 may be implemented, for example, with a comparator that binarizes the sinusoidal wave signal DV to generate a square-wave drive clock signal CKD.

The amplifier circuit 70 includes Q/V conversion circuits 72 and 74 and a PGA circuit 76. From the physical quantity transducer 10, the detection signals S1 and S2, which are a differential pair of signals, are input to the Q/V conversion circuits 72 and 74. The Q/V conversion circuits 72 and 74 are charge-to-voltage conversion circuits. The Q/V conversion circuit 72 performs charge-to-voltage conversion of the detection signal S1, and the Q/V conversion circuit 74 performs charge-to-voltage conversion of the detection signal S2. The PGA circuit 76, which is a programmable gain amplifier, adjusts the gains of the amplified signals from the Q/V conversion circuits 72 and 74 and outputs detection signals SA1 and SA2 to the A/D conversion circuit 80.

In addition, as illustrated in FIG. 2, the circuit device 20 includes a digital processing circuit 92. The digital processing circuit 92 receives the digital output signal DQ from the mixer 90, performs various digital processing operations, and outputs a final digital output signal DSQ. For example, the digital processing circuit 92 includes a digital correction circuit 94 and a digital filter 96. The digital correction circuit 94 performs digital correction such as zero-point correction and gain correction. The digital filter 96 performs digital filtering such as low-pass filtering on a digitally corrected signal from the digital correction circuit 94.

As described above, the circuit device 20 in the present embodiment includes the drive circuit 30, the phase-locked loop circuit 40, the A/D conversion circuit 80, and the mixer 90. The drive circuit 30 drives the physical quantity transducer 10, and the phase-locked loop circuit 40 generates the digital sinusoidal wave signal DSW phase-locked to the drive clock signal CKD from the drive circuit 30. The A/D conversion circuit 80 performs A/D conversion of a detection signal of the physical quantity transducer 10, and the mixer 90 performs a multiplication between the digital detection signal ADQ after the A/D conversion and the digital sinusoidal wave signal DSW. In detail, the phase-locked loop circuit 40 performs a phase comparison between the drive clock signal CKD and the digital sinusoidal wave signal DSW or the digital phase signal DPH to generate the digital sinusoidal wave signal DSW phase-locked to the drive clock signal CKD. In such a manner, A/D conversion of a detection signal, which has been output from the physical quantity transducer 10 by driving of the drive circuit 30, is performed by the A/D conversion circuit 80, and a multiplication between the digital detection signal ADQ after the A/D conversion and the digital sinusoidal wave signal DSW is performed by the mixer 90, which enables a physical quantity to be detected from the detection signal of the physical quantity transducer 10. That is, digital processing using the digital detection signal ADQ and the digital sinusoidal wave signal DSW enables detection of a physical quantity. For example, in the present embodiment, a signal frequency-modulated by driving of the drive circuit 30 is converted from analog to digital at a speed higher than the speed of the modulating frequency by the A/D conversion circuit 80. Then, using the sinusoidal wave signal DSW digitally generated based on the drive clock signal CKD corresponding to the modulating signal, the digital mixer 90 demodulates the signal from the digital detection signal ADQ from the A/D conversion circuit 80 through digital processing.

In such a way, since the detection signal is demodulated by the mixer 90 using a digital signal, not an analog signal, the effects of low frequency noise, such as 1/f noise, generated by an analog circuit may be removed. In addition, since the mixer 90 uses the sinusoidal wave signal DSW, not a square wave signal, to demodulate a desired signal from the digital detection signal ADQ, generation of folding noise, which is generated when a square wave signal is used, may be reduced. Thereby, for example, zero-point correction and so on may be improved. In addition, according to the present embodiment, phase comparison is performed between the drive clock signal CKD and the digital sinusoidal wave signal DSW or the digital phase signal DPH, thereby generating the digital sinusoidal wave signal DSW phase-locked to the drive clock signal CKD. Accordingly, it is unnecessary to provide, for example, an analog multiplier circuit that multiplies the frequency of a drive clock signal, and therefore a reduction in the area and a decrease in the power consumption of the circuit device 20 may be achieved.

For example, as a first comparative example of the present embodiment, there is a technique of detecting a desired signal using an analog synchronous detection circuit based on an amplified analog detection signal from an amplifier circuit and a square-wave synchronous signal from a drive circuit.

However, in the technique of the first comparative example, an analogue filter circuit, which performs low-pass filtering on an analog output voltage from the synchronous detection circuit, and an A/D conversion circuit, which performs A/D conversion of an output voltage of the filter circuit, are provided after the synchronous detection circuit. Accordingly, low frequency noise, such as 1/f noise, generated in the analog filter circuit and the A/D conversion circuit is superimposed on a detection result of a circuit device, which is disadvantageous in that the effect of low frequency noise of an analog circuit is not removed.

In addition, as a second comparative example of the present embodiment, there is a technique of directly sampling and holding an amplified analog detection signal from an amplifier circuit based on a synchronization signal from a drive circuit and converting the sampled and held voltage from analog to digital by an A/D conversion circuit.

However, in the technique of the second comparative example, the modulated detection signal is directly mixed by a sample-and-hold circuit, and thereby the signal is converted to the DC level. Folding noise occurs due to the sampling and holding operations, and therefore it is desired that the folding noise be reduced by a band-pass filter prior to the sample-and-hold circuit. For example, when the modulating frequency is 50 kHz, the band-pass filter has a filter characteristic of passing signals in a band centered at 50 kHz; however, for reducing folding noise, it is desired that sufficient attenuation be ensured, for example, at a frequency of 150 kHz. Constructing an analog circuit band-pass filter that satisfies this condition is difficult in terms of circuit area, circuit size, and consumed current when the order of the filter and various elements are taken into account.

In addition, as a third comparative example of the present embodiment, there is considered a technique of configuring a digital mixer to perform digital demodulation such that a drive signal is converted from analog to digital by a first A/D conversion circuit, A/D conversion of a detection signal is performed by a second A/D conversion circuit, and a multiplication between the digital signals after the A/D conversion is performed.

However, in the technique of the third comparative example, two A/D conversion circuits are to be used, leading to an increase in the size of the circuit device and an increase in power consumption. In addition, there is a problem in that, in order to adjust the phase, the adjustment is to be performed by digital processing or with an analog circuit.

In addition, in the technique of WO2015/072090 described above, an analog multiplier that multiplies the frequency of a signal from a drive circuit is provided. However, it is desired for the analog multiplier to use an analog phase comparison circuit and an analog charge pump circuit, an analog filter, and a voltage-controlled oscillation circuit that generates an oscillation signal using an inductor and a vibrator. Furthermore, these circuits are problematic in that the circuit areas are very larger and the power consumption amounts are also larger than those of the digital phase-locked loop circuit 40 in the present embodiment. For example, in order to perform digital synchronous detection at a high resolution, it is desired to increase the multiplication factor of a PLL circuit, which is a multiplier, to increase the frequency of an output clock signal. However, increasing the frequency of an output clock signal of the PLL circuit further increases the circuit area of the PLL circuit.

In this regard, according to the present embodiment, a detection signal is demodulated by performing a multiplication between the digital detection signal ADQ and the digital sinusoidal wave signal DSW. Accordingly, the low frequency noise, which is problematic in the first comparative example, such as 1/f noise caused by an analog circuit, is not superimposed on the band of a detection signal. Therefore, improvement in the long-term stability may be made.

In addition, according to the present embodiment, constrains of the folding noise on a filter, which is problematic in the second comparative example, may be mitigated, for example, by improving the sampling rate of the A/D conversion circuit 80.

In addition, according to the present embodiment, since an A/D conversion circuit that performs A/D conversion of a signal of a drive circuit becomes unnecessary, two A/D conversion circuits as in the third comparative example become unnecessary and therefore the circuit area may be reduced.

In addition, according to the present embodiment, a PLL circuit, which is an analog multiplier, provided in the circuit device disclosed in WO2015/072090 is unnecessary, which enables a reduction in the circuit area and a decrease in the power consumption. That is, according to the present embodiment, a mechanism equivalent to the PLL circuit may be implemented using only digital signal processing, which is advantageous in terms of the consumed current and the circuit area. In addition, a mechanism corresponding to the PLL circuit is implemented only by digital computation and therefore is resistant to variations and temperature fluctuations, making it easy to implement a fine adjustment mechanism for phase adjustment and so on.

### 2. Phase-Locked Loop Circuit

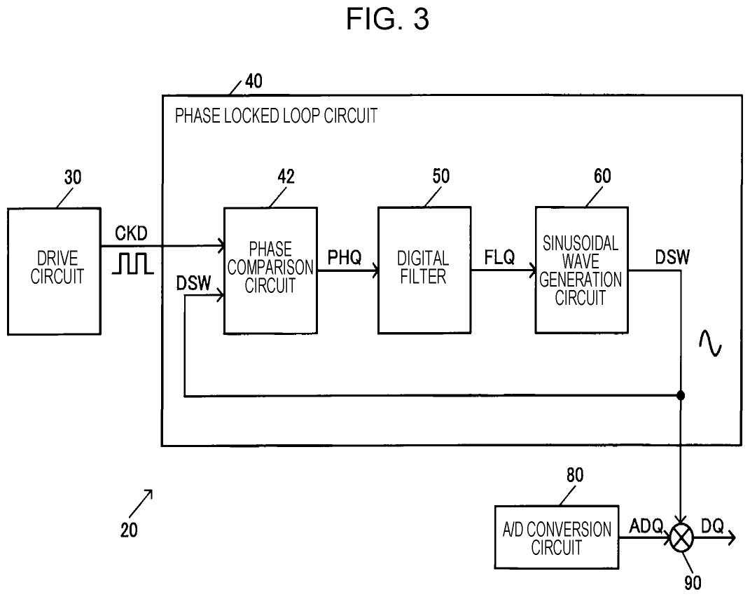

Various exemplary configurations of the phase-locked loop circuit 40 will now be described. As illustrated in FIG. 3, the phase-locked loop circuit 40 includes a phase comparison circuit 42, a digital filter 50, and a sinusoidal wave generation circuit 60.

The phase comparison circuit 42 performs a phase comparison between the drive clock signal CKD and the digital sinusoidal wave signal DSW. For example, the phase comparison circuit 42 samples digital values of the sinusoidal wave signal DSW at edge timings of the drive clock signal CKD. That is, the phase comparison circuit 42 is a circuit that samples and holds the digital values of the sinusoidal wave signal DSW. The digital filter 50 performs digital filtering on a phase comparison result signal PHQ of the phase comparison circuit 42. For example, the digital filter 50 performs digital filtering in which the digital values of the phase comparison result signal PHQ are integrated by an integrator. Specifically, the digital filter 50 performs digital filtering using digital proportional and integral (PI) control of digital values of the phase comparison result signal PHQ. This digital filtering is low-pass filtering that acts as a loop filter of the phase-locked loop circuit 40. The sinusoidal wave generation circuit 60 outputs the digital sinusoidal wave signal DSW based on a filter output signal FLQ of the digital filter 50. For example, the sinusoidal wave generation circuit 60 generates the digital sinusoidal wave signal DSW, which is a sequence of digital values representing a sinusoidal waveform, based on digital values of the filter output signal FLQ. The digital values representing a sinusoidal waveform may be generated using, for example, an algorithm approximating a sinusoidal wave, such as recurrence relations of coordinate rotation digital computer (CORDIC).

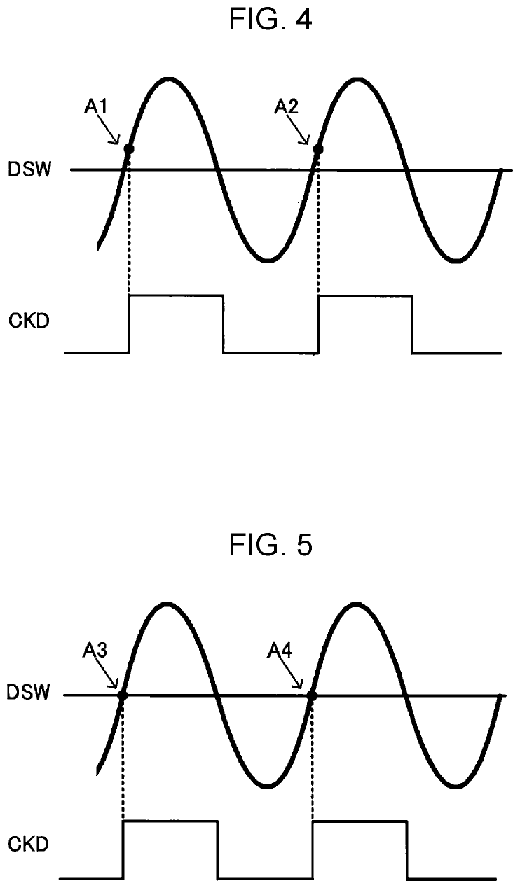

For example, FIGS. 4 and 5 illustrate phase locking between the digital sinusoidal wave signal DSW and the drive clock signal CKD. The sinusoidal wave signal DSW is a signal in which the digital values of a sinusoidal waveform are signal values. The phase comparison circuit 42 samples and holds digital values, which are signal values of the sinusoidal wave signal DSW at the edge timings of the drive clock signal CKD as indicated by A1 and A2 in FIG. 4. The digital values of the sinusoidal wave signal DSW are, for example, floating-point digital values. Although FIG. 4 illustrates sampling of digital values of the sinusoidal wave signal DSW at rising edges of the drive clock signal CKD, sampling may be performed at falling edges of the drive clock signal CDK. Then, as illustrated at A3 and A4 in FIG. 5, the phase-locked loop circuit 40 performs, for example, digital processing for phase locking that causes the zero-crossing timing of the sinusoidal wave signal DSW to match the edge timing of the drive clock signal CKD. For example, the sinusoidal wave generation circuit 60 generates the digital sinusoidal wave signal DSW based on the digital value of the filter output signal FLQ from the digital filter 50 based on the phase comparison result signal PHQ of the phase comparison circuit 42, for example, such that the digital sinusoidal wave signal DSW has a frequency at which the zero-crossing timing of the sinusoidal wave signal DSW matches the edge timing of the drive clock signal CKD. Although FIG. 5 illustrates the case where feedback control is performed such that the zero-crossing timings of the sinusoidal wave signal DSW matches the edge timings of the drive clock signal CKD, the present embodiment is not limited to this. When phase adjustment as described later is performed in the phase-locked loop circuit 40, feedback control is performed such that there is a predetermined phase difference due to phase adjustment between the zero-crossing timing of the sinusoidal wave signal DSW and the edge timing of the drive clock signal CKD.

Although FIG. 3 illustrates that the phase comparison circuit 42 performs the phase comparison between the drive clock signal CKD and the digital sinusoidal wave signal DSW, the phase comparison circuit 42 as illustrated in FIG. 6 may perform a phase comparison between the drive clock signal CKD and the digital phase signal DPH. In this case, feedback control is performed, for example, such that there is a match or a predetermined phase difference between the phase of the drive clock signal CKD and the phase represented by the phase signal DPH.

In such a manner, with the phase-locked loop circuit 40 configured as illustrated in FIG. 3 or FIG. 6, a phase comparison between the drive clock signal CKD and the sinusoidal wave signal DSW or the phase signal DPH is performed in the phase comparison circuit 42, digital filtering on a phase comparison result signal is performed in the digital filter 50, and the digital sinusoidal wave signal DSW is generated by the sinusoidal wave generation circuit 60. In such a manner, all of the phase comparison, filtering, and sinusoidal wave generation are performed by digital processing. Accordingly, as compared with the technique of WO2015/072090 that uses an analog PLL circuit, a reduction in the area of the circuit and a decrease in the power consumption may be achieved. For example, in the technique of multiplying the frequency of a signal from a drive circuit using an analog PLL circuit, in order to generate a digital sinusoidal wave signal at a high resolution, it is desired to increase the multiplication factor of the PLL circuit to increase the frequency of an output clock signal. An increase in the frequency of an output clock signal of the PLL circuit leads to a further increase in the circuit area and power consumption. In contrast, with the phase-locked loop circuit 40 illustrated in FIG. 3 or FIG. 6, in order to generate the digital sinusoidal wave signal DSW at a high resolution, only an increase in the frequency of an operational clock signal of the phase-locked loop circuit 40 is sufficient. For example, there is an advantage in that the digital sinusoidal wave signal DSW at a high resolution may be generated only by increasing the frequency of a clock signal acting as a master clock that causes the phase-locked loop circuit 40 to operate. For example, the resolution of the floating point of a digital value of the sinusoidal wave signal DSW may be increased. The frequency of an operational clock signal is, by way of example, a frequency of 10 MHz or more.

In addition, in the present embodiment, the phase comparison circuit 42 samples the digital sinusoidal wave signal DSW at edge timings of the drive clock signal CKD. For example, as described with reference to A1 and A2 in FIG. 4, the digital values of the sinusoidal wave signal DSW at edge timings of the drive clock signal CKD are held in the phase comparison circuit 42. Then, digital filtering based on the held digital values is performed and, in the sinusoidal wave generation circuit 60, the sinusoidal wave signal DSW phase-locked to the drive clock signal CKD is generated. In such a way, with a digital circuit having a simple configuration in which the digital sinusoidal wave signal DSW is sampled at edge timings of the drive clock signal CKD, a phase comparison between the drive clock signal CKD and the sinusoidal wave signal DSW may be achieved. This enables achievement of a reduction in the area and a decrease in the power consumption of the circuit device 20.

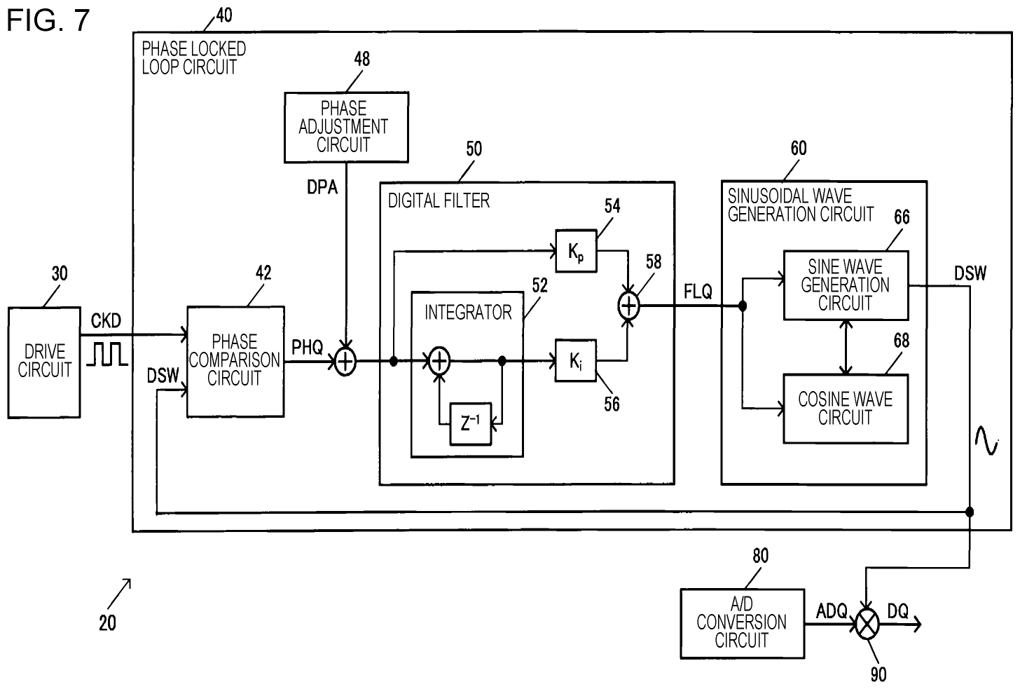

FIG. 7 illustrates a detailed exemplary configuration of the phase-locked loop circuit 40. The phase comparison circuit 42 samples and holds digital values of the sinusoidal wave signal DSW at edge timings of the drive clock signal CKD. The digital filter 50 includes an integrator 52, arithmetic processors 54 and 56, and an adder 58. The integrator 52 performs an integration of the digital value of the phase comparison result signal PHQ. The arithmetic processors 54 and 56 multiply the inputs by Kₚ and Kᵢ, respectively, which are proportional gains, and the adder 58 adds the output values of the arithmetic processors 54 and 56. Thereby, digital filtering using PI control is achieved. The sinusoidal wave generation circuit 60 includes a sine wave circuit 66, which generates a sine wave signal, and a cosine wave circuit 68, which generates a cosine wave signal. A sine wave signal generated by the sine wave circuit 66 is output as the digital sinusoidal wave signal DSW from the sinusoidal wave generation circuit 60.

For example, the transfer function in an open-loop of the phase-locked loop circuit 40 illustrated in FIG. 7 may be expressed by equation (1) given below, and this transfer equation may be approximated as equation (2) given below. The open loop is, for example, a loop in which the input node of the digital filter 50 is the input and the output node of the phase comparison circuit 42 is the output.

$${H}_{open} ( z ) = ( {K}_{p} + \frac{{K}_{i}}{1 - {z}^{- 1}} ) \frac{1}{1 - {z}^{- 1}} \qquad ( 1 )$$

$${H}_{open} ( s ) ≅ ( {K}_{p} + \frac{{K}_{i} {f}_{m}}{s} ) \frac{{f}_{m}}{s} \qquad ( 2 )$$

The first term of equation (1) given above is a transfer function of a digital filter that performs PI control, and the second term is a transfer function representing integral characteristics of the sinusoidal wave generation circuit 60 and so on. Here, fₘ is an operating clock frequency of the phase-locked loop circuit 40. The phase-locked loop circuit 40 operates based on a clock signal of the frequency, fₘ, to perform digital processing.

The closed-loop transfer function of the phase-locked loop circuit 40 based on the open-loop transfer functions of equations (1) and (2) given above may be determined as represented by equation (3) given below.

$${H}_{close} ( s ) ≅ \frac{{H}_{open} ( s )}{1 - {H}_{open} ( s )} = \frac{{f}_{m} {K}_{p} s + {f}_{m}^{2} {K}_{i}}{{s}^{2} - {f}_{m} {K}_{p} s - {f}_{m}^{2} {K}_{i}} = \frac{{H}^{′} ( s )}{{s}^{2} + 2 {ζω}_{c} S + {ω}_{c}^{2}} \qquad ( 3 )$$

In equation (3) given above, ω_{c} is a cut-off frequency of the loop filter of the phase-locked loop circuit 40, and ζ is a damping factor.

Then, in order to set ω_{c}, which is a cut-off frequency of the loop filter, to a desired frequency, Kₚ and Kᵢ, which are proportional gains in PI control, may be set as in equation (4) given below.

$${K}_{p} = - \frac{2 {ζω}_{c}}{{f}_{m}} {K}_{i} = - {( \frac{{ω}_{c}}{{f}_{m}} )}^{2} \qquad ( 4 )$$

For example, in accordance with fₘ, which is the operating clock frequency of the phase-locked loop circuit 40, Kₚ and Kᵢ are set so that a desired cut-off frequency is obtained. In addition, ζ, which is a damping factor, is set so that the filter characteristics are proper characteristics.

The sinusoidal wave generation circuit 60 will now be described in detail. The sine wave circuit 66 of the sinusoidal wave generation circuit 60 generates a sine wave signal by using a recurrence relation of equation (5) given below. In addition, the cosine wave circuit 68 generates a cosine wave signal by using a recurrence relation of equation (6) given below. Then, A and B in equations (5) and (6) given below are approximated as in equations (7) given below.

$$sin ( 2 π {f}_{dr} t ( n + 1 ) ) = B sin ( 2 π {f}_{dr} t ( n ) ) + A cos ( 2 π {f}_{dr} t ( n ) ) \qquad ( 5 )$$

$$cos ( 2 π {f}_{dr} t ( n + 1 ) ) = - A sin ( 2 π {f}_{dr} t ( n ) ) + B cos ( 2 π {f}_{dr} t ( n ) ) \qquad ( 6 )$$

$$A = sin ( 2 π {f}_{dr} Δ t ) ≅ 2 π {f}_{dr} Δ t B = cos ( 2 π {f}_{dr} Δ t ) ≅ 1 \qquad ( 7 )$$

Equations (5), (6), and (7) given above are recurrence relations based on addition theorem of trigonometric functions. Here, far is a drive frequency of the drive clock signal CKD and, by way of example, f_{dr}=about 50 KHz to 100 kHz. In addition, t(n+1) corresponds to the timing of the current clock of a clock signal with which the phase-locked loop circuit 40 operates, and t(n) corresponds to the timing of the previous clock of the clock signal. In addition, Δt=t(n+1)−t(n). In equation (7), assuming that Δt is sufficiently small, the values of A and B are approximated.

As a value of the filter output signal FLQ, A=2πf_{dr}Δt in equations (5) to (7) is input as a value of the filter output signal FLQ to the sinusoidal wave generation circuit 60. The unit of this value is, for example, radian. For example, when the period of the drive clock signal CKD described with reference to FIGS. 4 and 5 is T_{dr}, f_{dr}=1/T_{dr} and therefore A=2πf_{dr}Δt=2π(Δt/T_{dr}). Accordingly, A=2πf_{dr}Δt=2π(Δt/T_{dr}) is a phase step size corresponding to Δt, which is a clock step size of a clock signal of the phase-locked loop circuit 40. For example, assuming that the operating clock frequency of the phase-locked loop circuit 40 is fₘ, Δt=1/fm, and therefore A can be expressed as A=2πf_{dr}Δt=2π(f_{dr}/fₘ).

Then, when A=2πf_{dr}Δt is input to the sine wave circuit 66, as expressed in equation (5) given above, the sine wave circuit 66 multiplies cos (2πf_{dr}t (n)), which is the value of a cosine wave signal at the previous timing, by A=2πf_{dr}Δt, which is the value of the filter output signal FLQ. Then, the sine wave circuit 66 adds this multiplication result to sin (2πf_{dr}t (n)), which is the value of a sine wave signal at the previous timing, thereby obtaining sin (2πf_{dr}t (n+1)), which is the value of a sine wave signal at the current timing. Thereby, the digital sinusoidal wave signal DSW is generated. Here, as expressed in equations (7) given above, B is approximated to one.

In addition, as expressed in equation (6) given above, the cosine wave circuit 68 multiplies sin (2πf_{dr}t (n)), which is the value of a sine wave signal at the previous timing, by A=2πf_{dr}Δt, which is the value of the filter output signal FLQ. Then, the cosine wave circuit 68 subtracts this multiplication result from cos (2πf_{dr}t (n)), which is the value of a cosine wave signal at the previous timing, thereby obtaining cos (2πf_{dr}t (n+1)), which is the value of a cosine wave signal at the current timing. The value of the sine wave signal at the previous timing, sin (2πf_{dr}t (n)), and the value of the cosine wave signal at the previous timing, cos (2πf_{dr}t (n)), are held, for example, in storages of the sine wave circuit 66 and the cosine wave circuit 68.

As described above, in the present embodiment, the sinusoidal wave generation circuit 60 generates a sine wave signal and a cosine wave signal at the current timing based on a sine wave signal and a cosine wave signal at the previous timing and the filter output signal FLQ and outputs the generated sine wave signal as the digital sinusoidal wave signal DSW. For example, the sinusoidal wave signal DSW is generated by determining, by using the recurrence relations described using equations (5) to (7) given above, the values of the sine wave signal and the cosine wave signal at the current timing from the values of the sine wave signal and the cosine wave signal at the previous timing and the filter output signal FLQ. In such a way, the sinusoidal wave signal DSW with a high resolution may be generated even by simple processing and even with a simple configuration, enabling both improvement in detection accuracy and a reduction in circuit size to be achieved.

In addition, as illustrated in FIG. 7, the sinusoidal wave generation circuit 60 includes the sine wave circuit 66 and the cosine wave circuit 68. In addition, as described using equation (5) given above, the sine wave circuit 66 determines a value of the sine wave signal at the current timing by adding a multiplication result between the value of the cosine wave signal at the previous timing and the value of the filter output signal FLQ to the value of the sine wave signal at the previous timing. For example, the sine wave circuit 66 multiplies cos (2πf_{dr}t (n)) by A=2πf_{dr}Δt and adds this multiplication result to sin (2πf_{dr}t (n)), thereby obtaining sin (2πf_{dr}t (n+1)). In addition, as described using equation (6) given above, the cosine wave circuit 68 generates a cosine wave signal at the current timing by subtracting a multiplication result between the value of the sine wave signal at the previous timing and the value of the filter output signal FLQ from the value of the cosine wave signal at the previous timing. For example, the cosine wave circuit 68 multiplies sin (2πf_{dr}t (n)) by A=2πf_{dr}Δt and subtracts this multiplication result from cos (2πf_{dr}t (n)), thereby obtaining cos (2πf_{dr}t (n+1)). In such a way, the digital sinusoidal wave signal DSW with a high resolution may be generated by simple processing using the predetermined recurrence relations as described using equations (5) to (7) given above. For example, the digital sinusoidal wave signal DSW may be generated by simple arithmetic processing that imposes a small processing load, and thus a reduction in size of the sinusoidal wave generation circuit 60 and so on may be achieved.

In addition, as illustrated in FIG. 7, the phase-locked loop circuit 40 includes a phase adjustment circuit 48. Then, the phase adjustment circuit 48 adds the value of a digital phase adjustment signal DPA to the value of the phase comparison result signal PHQ. For example, there is ideally a phase difference of 90 degrees between a drive signal and a detection signal of the physical quantity transducer 10, and the phase changes by only 90 degrees in the Q/V conversion circuits 72 and 74 illustrated in FIG. 2, and therefore the digital detection signal ADQ may be in phase with the sinusoidal wave signal DSW in the mixer 90. However, the phase difference between the drive signal and the detection signal is actually not 90 degrees in some cases, and, if no phase adjustment is provided, the digital detection signal ADQ becomes out of phase with the sinusoidal wave signal DSW in the mixer 90. To address this, in the present embodiment, the phase adjustment circuit 48 is provided to add the value of the phase adjustment signal DPA to the value of the phase comparison result signal PHQ. For example, the phase adjustment circuit 48 adds, to the value of the phase comparison result signal PHQ, such a value of the phase adjustment signal DPA so as to cause the digital detection signal ADQ and the sinusoidal wave signal DSW to have the same phase in the mixer 90. In such a way, the digital detection signal ADQ and the sinusoidal wave signal DSW are in phase with each other in the mixer 90. This may reduce a problem such as a decrease in sensitivity due to the digital detection signal ADQ and the sinusoidal wave signal DSW being out of phase.

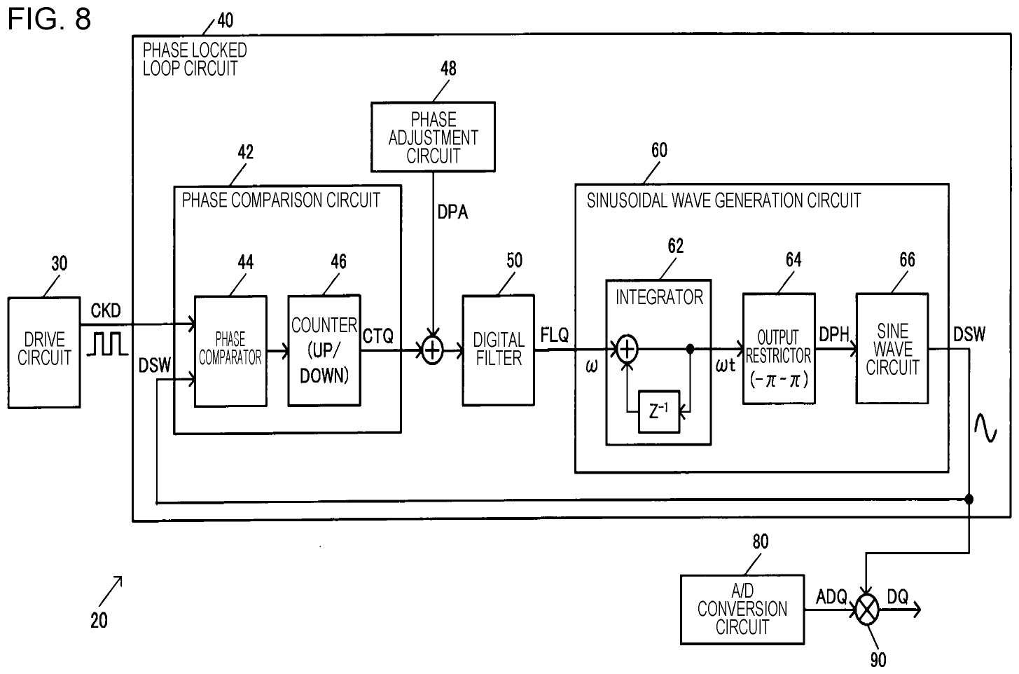

FIG. 8 illustrates another detailed exemplary configuration of the phase-locked loop circuit 40. The phase-locked loop circuit 40 illustrated in FIG. 8 calculates a phase difference between the drive clock signal CKD and the sinusoidal wave signal DSW based on an operational clock signal of the phase-locked loop circuit 40. For example, the phase-locked loop circuit 40 compares the phases of the drive clock signal CKD and the sinusoidal wave signal DSW by using an operational clock signal of a high-speed frequency, fₘ, and outputs a counter output signal CTQ that indicates what number of clocks of the operational clock signal correspond to a phase difference. For example, the phase comparison circuit 42 includes a phase comparator 44 and a counter 46. The phase comparator 44 is a circuit for comparing the phases of the drive clock signal CKD and the sinusoidal wave signal DSW. Specifically, the phase comparator 44 may be implemented with, for example, a data latch circuit, which latches a voltage level of the drive clock signal CKD based on an operational clock signal of the phase-locked loop circuit 40. The counter 46 performs up-count processing or down-count processing based on a result of a phase comparison. Specifically, the counter 46 performs up-count processing or down-count processing based on a latch result of a voltage level of the drive clock signal CKD and the sign of a digital value of the sinusoidal wave signal DSW. For example, if the phase of the sinusoidal wave signal DSW is delayed with respect to the drive clock signal CKD, the counter 46 performs up-count processing in a time period during which a latch result of the voltage level of the drive clock signal CKD is a high level and the sign of a digital value of the sinusoidal wave signal DSW is negative. In addition, if the phase of the sinusoidal wave signal DSW is advanced with respect to the drive clock signal CKD, the counter 46 performs up-count processing in a time period during which a latch result of the voltage level of the drive clock signal CKD is a low level and the sign of a digital value of the sinusoidal wave signal DSW is positive. Thereby, the phase comparison circuit 42 outputs the counter output signal CTQ as a phase comparison result signal. Then, the digital filter 50 performs digital filtering on the counter output signal CTQ of the counter 46. As the digital filter 50, for example, a circuit having a configuration similar to the configuration described with reference to FIG. 7 may be employed. The configuration of the digital filter 50 is not limited to the configuration described with reference to FIG. 7 and may be implemented in various modified manners.

In such a configuration, whether the phase of the sinusoidal wave signal DSW is delayed or advanced with respect to the drive clock signal CKD may be determined by the counter 46 performing up-count processing or down-count processing, which enables generation of the sinusoidal wave signal DSW phase-locked to the drive clock signal CKD. Accordingly, the sinusoidal wave signal DSW phase-locked to the drive clock signal CKD may be generated by simple digital processing.

The sinusoidal wave generation circuit 60 includes, for example, an integrator 62, an output restrictor 64, and the sine wave circuit 66. The integrator 62 performs processing of integrating the value of the filter output signal FLQ of the digital filter 50. Thereby, processing of determining ωt corresponding to the phase from ω is performed. The output restrictor 64 performs processing of restricting an output value of the integrator 62 to a range of −π to π. For example, if ωt, which is an output value of the integrator 62 exceeds π, 2π is subtracted, and if ωt falls below −π, 2π is added, thus performing the restricting processing in the output restrictor 64. The sine wave circuit 66 generates the digital sinusoidal wave signal DSW based on the digital phase signal DPH output by the output restrictor 64. For example, the phase signal DPH corresponds to ωt, and the sine wave circuit 66 performs arithmetic processing of determining sin (ωt) based on the phase signal DPH corresponding to ωt to generate the digital sinusoidal wave signal DSW. For example, the sine wave circuit 66 performs arithmetic processing of determining a digital value of the sinusoidal wave signal DSW by using an algorithm approximating a sinusoidal wave, such as CORDIC.

In such a manner, as illustrated in FIG. 8, the sinusoidal wave generation circuit 60 converts the filter output signal FLQ of the digital filter 50 to the digital phase signal DPH and generates the digital sinusoidal wave signal DSW based on the digital phase signal DPH. For example, the sinusoidal wave generation circuit 60 determines ωt corresponding to the phase signal DPH from ω corresponding to the value of the filter output signal FLQ and performs arithmetic processing of determining sin (ωt) from the phase, ωt, by using a predetermined algorithm, thereby determining the digital value of the sinusoidal wave signal DSW. In such a way, from a phase comparison result between the drive clock signal CKD and the sinusoidal wave signal DSW, the phase signal DPH for phase locking to the drive clock signal CKD is determined, and the sinusoidal wave signal DSW phase-locked to the drive clock signal CKD based on the determined phase signal DPH may be generated.

In addition, as illustrated in FIG. 8, the phase-locked loop circuit 40 includes the phase adjustment circuit 48. Then, the phase adjustment circuit 48 adds the value of the digital phase adjustment signal DPA to the value of the counter output signal CTQ from the counter 46 of the phase comparison circuit 42. For example, the phase adjustment circuit 48 adds, to the value of the counter output signal CTQ, such a value of the phase adjustment signal DPA as to cause the digital detection signal ADQ and the sinusoidal wave signal DSW are in the same phase at the mixer 90. This enables the digital detection signal ADQ and the sinusoidal wave signal DSW to be in phase with each other in the mixer 90. This may reduce a problem such as a decrease in sensitivity due to the digital detection signal ADQ and the sinusoidal wave signal DSW being out of phase.

FIG. 9 illustrates another detailed exemplary configuration of the phase-locked loop circuit 40. FIG. 9 differs from FIG. 8 in that FIG. 8 illustrates that the sinusoidal wave signal DSW is fed back to the phase comparison circuit 42 and, in contrast, FIG. 9 illustrates that the phase signal DPH is fed back to the phase comparison circuit 42. That is, FIG. 9 illustrates that the phase comparison circuit 42 uses the phase signal DPH of the sinusoidal wave signal DSW to perform a phase comparison between the phase signal DPH and the drive clock signal CKD. In such a manner, the phase-locked loop circuit 40 in the present embodiment performs a phase comparison between the drive clock signal CKD and the sinusoidal wave signal DSW or the phase signal DPH of the sinusoidal wave signal DSW to generate the sinusoidal wave signal DSW phase-locked to the drive clock signal CKD.

### 3. Continuous-time ΔΣ A/D Conversion Circuit

In the present embodiment, as the A/D conversion circuit 80, for example, a delta-sigma (ΔΣ) A/D conversion circuit is used. In the ΔΣ A/D conversion circuit, SNR, which is a signal-to-noise ratio, may be improved by using noise shaping and so on. In addition, the ΔΣ A/D conversion circuit is of a discrete-time type or a continuous-time type. In the discrete-time type, a sample-and-hold circuit is provided in an input section, and therefore folding noise occurs due to sampling of an input signal performed by the sample-and-hold circuit. Therefore, it is desired to provide an anti-aliasing filter for reducing the folding noise prior to the A/D conversion circuit, which causes a problem in that the circuit area increases by the area of the anti-aliasing filter. For example, the anti-aliasing filter passes signals of drive frequencies, such as, 50 kHz but has to attenuate signals of frequencies higher than the drive frequencies by using steep filter characteristics in order to reduce degradation in SNR due to the folding noise. Therefore, in order to reduce degradation in SNR, the circuit area of the anti-aliasing filter further increases. In this case, a technique of raising the sampling rate of the sample-and-hold circuit of the input section may be considered. However, this leads to an increase in power consumption.

To address the problem, in the present embodiment, a continuous-time ΔΣ A/D conversion circuit is used as the A/D conversion circuit 80. In the continuous-time type, a sample-and-hold circuit is not provided in the input section and therefore it is unnecessary to provide an anti-aliasing filter prior to the A/D conversion circuit 80, which enables a reduction in the circuit area and a decrease in the power consumption to be more achieved than in the discrete-time type. For example, in the continuous-time type, although folding noise and quantization noise occur in a portion of a quantizer at the final stage, the folding noise returns through a feedback path to the input and therefore is attenuated in the same way as the quantization noise due to the characteristics of a low pass filter of, for example, an integrator.

For example, the continuous-time ΔΣ A/D conversion circuit 80 includes at least one integrator and a quantizer, and an output signal of the quantizer is fed back to the integrator. The integrator performs an integration of a difference between an input signal and the fed-back output signal, and the quantizer quantizes an output signal of the integrator.

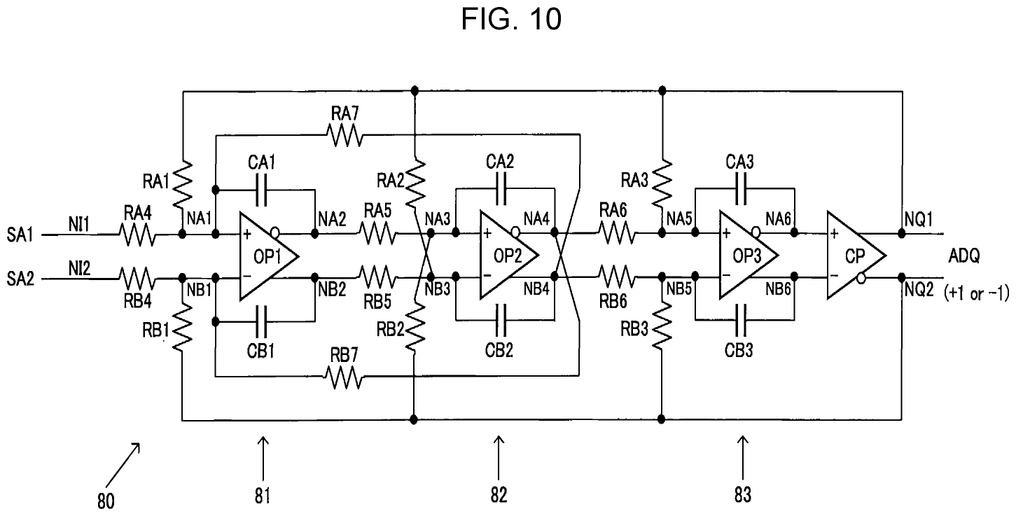

FIG. 10 illustrates an exemplary configuration of the continuous-time ΔΣ A/D conversion circuit 80. The configuration of the A/D conversion circuit 80 is not limited to the configuration illustrated in FIG. 10 and may be implemented as various modifications, such as omitting some of the components in the configuration, adding other components, and replacing some of the components with other components. For example, the A/D conversion circuit 80 illustrated in FIG. 10 is in a differential configuration but may be in a single-ended configuration.

The A/D conversion circuit 80 illustrated in FIG. 10 is in a third-order delta-sigma structure in which three integrators 81, 82, and 83 are provided. However, the number of orders of the delta sigma is not limited to this and may be two, or greater than or equal to four. In addition, in the A/D conversion circuit 80 illustrated in FIG. 10, for example, a comparator CP is provided as a quantizer after the integrator 83. Then, an output signal of the comparator CP is fed back to the inputs of the integrators 81, 82, and 83, thereby achieving delta-sigma A/D conversion.

For example, the integrator 81 includes resistors RA4 and RB4 to one ends of which the detection signals SA1 and SA2 are input, respectively, resistors RA1 and RB1 for feeding back output signals of the comparator CP, which is a quantizer, an operational amplifier OP1 for differential input and differential output, and feedback capacitors CA1 and CB1. The resistors RA4 and RB4 have one ends coupled to input nodes NI1 and NI2 of the detection signals SA1 and SA2 and the other ends coupled to nodes NA1 and NB1, respectively. The resistors RA1 and RB1 have one ends coupled to output nodes NQ1 and NQ2 of the comparator CP and the other ends coupled to the nodes NA1 and NB1, respectively. The operational amplifier OP1 includes a non-inverting input terminal coupled to the node NA1 and an inverting input terminal coupled to the node NB1. The capacitor CA1 has one end coupled to a node NA2 of an inverting output terminal of the operational amplifier OP1 and has the other end coupled to the node NA1 of the non-inverting input terminal of the operational amplifier OP1, such that a negative feedback loop is established. The capacitor CB1 has one end coupled to a node NB2 of a non-inverting output terminal of the operational amplifier OP1 and has the other end coupled to the node NB1 of the non-inverting input terminal of the operational amplifier OP1, such that a negative feedback loop is established.

The integrator 82 includes resistors RA5 and RB5 to one ends of which output signals of the preceding integrator 81 are input, respectively, resistors RA2 and RB2 for feeding back output signals of the comparator CP, an operational amplifier OP2 of differential input and differential output, and feedback capacitors CA2 and CB2. The resistors RA5 and RB5 have one ends coupled to the output-signal nodes NA2 and NB2 of the preceding integrator 81 and have the other ends coupled to nodes NA3 and NB3, respectively. The resistors RA2 and RB2 have one ends coupled to the output nodes NQ1 and NQ2 of the comparator CP and have the other ends coupled to the nodes NB3 and NA3, respectively. The operational amplifier OP2 includes a non-inverting input terminal coupled to the node NA3 and an inverting input terminal coupled to the node NB3. The capacitor CA2 has one end coupled to a node NA4 of an inverting output terminal of the operational amplifier OP2 and has the other end coupled to the node NA3 of a non-inverting input terminal of the operational amplifier OP2, such that a negative feedback loop is established. The capacitor CB2 has one end coupled to a node NB4 of the non-inverting output terminal of the operational amplifier OP2 and has the other end coupled to a node NB3 of the inverting input terminal of the operational amplifier OP2, such that a negative feedback loop is established. An output signal of the node NB4 of the integrator 82 is fed back via a feedback resistor RA7 to the node NA1 of the preceding integrator 81, and an output signal of the node NA4 of the integrator 82 is fed back via a feedback resistor RB7 to the node NB1 of the preceding integrator 81.

The integrator 83 includes resistors RA6 and RB6 to one ends of which output signals of the preceding integrator 82 are input, respectively, resistors RA3 and RB3 for feeding back output signals of the comparator CP, an operational amplifier OP3 of differential input and differential output, and feedback capacitors CA3 and CB3. The resistors RA6 and RB6 have one ends coupled to the output-signal nodes NA4 and NB4 of the preceding integrator 82 and have the other ends coupled to nodes NA5 and NB5, respectively. The resistors RA3 and RB3 have one ends coupled to the output nodes NQ1 and NQ2 of the comparator CP and have the other ends coupled to the nodes NA5 and NB5, respectively. The operational amplifier OP3 includes a non-inverting input terminal coupled to the node NA5 and an inverting input terminal coupled to the node NB5. The capacitor CA3 has one end coupled to a node NA6 of the inverting output terminal of the operational amplifier OP3 and has the other end coupled to the node NA5 of the non-inverting input terminal of the operational amplifier OP3, such that a negative feedback loop is established. The capacitor CB3 has one end coupled to a node NB6 of the non-inverting output terminal of the operational amplifier OP3 and has the other end coupled to the node NB5 of the inverting input terminal of the operational amplifier OP3, such that a negative feedback loop is established.

Of the comparator CP that is a quantizer, the non-inverting input terminal is coupled to the output-signal node NA6 of the preceding integrator 83 and the inverting input terminal is coupled to the output-signal node NB6 of the preceding integrator 83. Then, the digital detection signal ADQ is output from the output nodes NQ1 and NQ2 of the comparator CP. The comparator CP operates based on a clock signal serving as the master and, in synchronization with the clock signal, performs comparison processing of an output signal of the preceding integrator 83 to output data representing+1 or −1 as a delta-sigma output.

In such a manner, since the continuous-time ΔΣ A/D conversion circuit 80 is used in the present embodiment, it is unnecessary to provide an anti-aliasing filter prior to the A/D conversion circuit 80, which enables a reduction in the circuit area and a decrease in the power consumption of the circuit device 20 to be achieved.

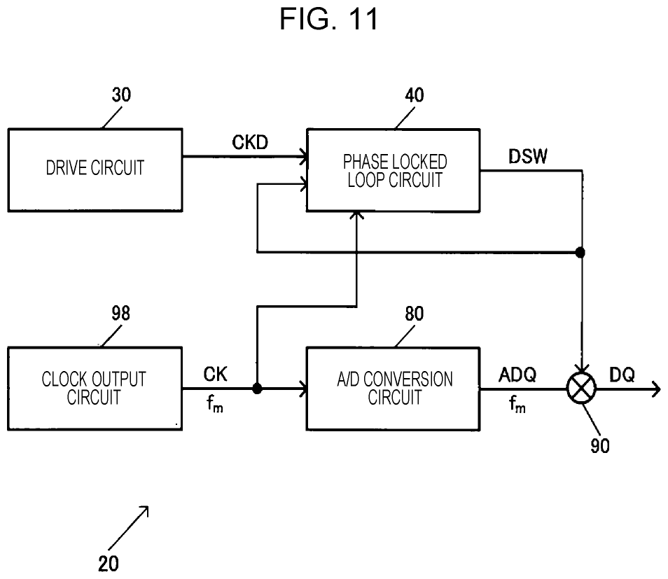

In addition, in the present embodiment, the operating clock frequency of the phase-locked loop circuit 40 and the data output frequency of the A/D conversion circuit 80 are equal. For example, as illustrated in FIG. 11, the circuit device 20 in the present embodiment includes a clock output circuit 98 that outputs a clock signal CK. The clock output circuit 98 may be implemented, for example, by a ring oscillator, LC resonant circuit, or multivibrator. Alternatively, the clock output circuit 98 may be a circuit that outputs an input clock signal from the outside as the clock signal CK or generates the clock signal CK using a vibrator such as quartz crystal vibrator.

The phase-locked loop circuit 40 and the A/D conversion circuit 80 each operate based on the clock signal CK. For example, the phase-locked loop circuit 40 operates based on the clock signal CK to output the sinusoidal wave signal DSW, for example, at a frequency fₘ of the clock signal CK. For example, the phase-locked loop circuit 40 outputs a digital value of the sinusoidal wave signal DSW in synchronization with the clock signal CK at the frequency fₘ. In the A/D conversion circuit 80, for example, the comparator CP, which is the quantizer illustrated in FIG. 10, operates based on the clock signal CK. Thereby, the A/D conversion circuit 80 outputs the digital detection signal ADQ at the data output frequency that is the frequency fₘ. For example, the A/D conversion circuit 80 outputs a digital value of the digital detection signal ADQ in synchronization with the clock signal CK of the frequency fₘ. Then, the mixer 90 performs a multiplication between the digital detection signal ADQ of the data output frequency that is the frequency fₘ and the sinusoidal wave signal DSW the digital value of which is output at the frequency fₘ. This enables the mixer 90 to perform a multiplication between the digital detection signal ADQ and the sinusoidal wave signal DSW that are input at the same frequency fₘ, and thus the mixer 90 may perform an appropriate multiplication to output the output signal DQ.

For example, in the present embodiment, the resolution of the sinusoidal wave signal DSW may be set using the frequency fₘ of the clock signal CK. In addition, as described by equation (4) given above, the characteristics of the loop filter of the phase-locked loop circuit 40 is set by the frequency fₘ. In addition, the sampling rate of the comparator CP, which is a quantizer in the A/D conversion circuit 80 illustrated in FIG. 10 may also be set by the frequency fₘ. Accordingly, there is an advantage in that these settings may be implemented by using the frequency fₘ that is uncorrelated with the drive frequency f_{dr} of the drive circuit 30. For example, in the technique of WO2015/072090 described above, since a sinusoidal wave signal is generated based on a signal of a frequency obtained by multiplying a drive frequency using a PLL circuit, these settings are not performed in a manner uncorrelated with the drive frequency. In this regard, the configuration of the present embodiment is advantageous over the exiting technique.

As described above, the circuit device in the present embodiment includes a drive circuit configured to drive a physical quantity transducer, a phase-locked loop circuit configured to generate a digital sinusoidal wave signal phase-locked to a drive clock signal from the drive circuit, an A/D conversion circuit configured to perform A/D conversion of a detection signal of the physical quantity transducer, and a mixer configured to perform a multiplication between the digital detection signal after the A/D conversion and the digital sinusoidal wave signal. The phase-locked loop circuit is configured to perform a phase comparison between the drive clock signal and the digital sinusoidal wave signal or a digital phase signal of the digital sinusoidal wave signal to generate the digital sinusoidal wave signal phase-locked to the drive clock signal.

According to the present embodiment, A/D conversion of a detection signal, which is output from the physical quantity transducer by driving of the drive circuit, is performed by the A/D conversion circuit, and a multiplication between the digital detection signal ADQ after the A/D conversion and the digital sinusoidal wave signal is performed by the mixer, which enables a physical quantity to be detected from the detection signal of the physical quantity transducer. In such a way, the detection signal is demodulated by the mixer using a digital signal, not an analog signal, which enables detection of the physical quantity in which low frequency noise generated by an analog circuit is removed.

In addition, in the present embodiment, the phase-locked loop circuit includes a phase comparison circuit configured to perform the phase comparison between the drive clock signal and the digital sinusoidal wave signal or the digital phase signal, a digital filter configured to perform digital filtering on a phase comparison result signal of the phase comparison circuit, and a sinusoidal wave generation circuit configured to output the digital sinusoidal wave signal based on a filter output signal of the digital filter.

In such a way, the phase comparison, filtering, and sinusoidal wave generation may be performed by digital processing, which enables a reduction in the circuit area and a decrease in the power consumption.

In addition, in the present embodiment, the phase comparison circuit may be configured to sample the digital sinusoidal wave signal at an edge timing of the drive clock signal.

In such a way, a phase comparison between a drive clock signal and a sinusoidal wave signal may be performed by simple processing in which digital sinusoidal wave signals are sampled at the edge timings of drive clock signal.

In addition, in the present embodiment, the phase-locked loop circuit may further include a phase adjustment circuit configured to add a value of a digital phase adjustment signal to a value of the phase comparison result signal.

In such a way, a digital detection signal and a digital sinusoidal wave signal may be in phase with each other in the mixer, which may reduce degradation in performance caused when the digital detection signal and the digital sinusoidal wave signal are out of phase.

In addition, in the present embodiment, the sinusoidal wave generation circuit may be configured to generate, based on a sine wave signal and a cosine wave signal at the previous timing and the filter output signal, a sine wave signal and a cosine wave signal at the current timing and to output the sine wave signal as the digital sinusoidal wave signal.

In such a way, a digital sinusoidal wave signal with a high resolution may be generated even by simple processing or with a simple configuration, enabling both improvement in the detection accuracy and a reduction in circuit size to be achieved.

In addition, in the present embodiment, the sinusoidal wave generation circuit may include a sine wave circuit configured to determine a value of the sine wave signal at the current timing by adding a multiplication result between a value of the cosine wave signal at the previous timing and a value of the filter output signal to a value of the sine wave signal at the previous timing. In addition, the sinusoidal wave generation circuit may include a cosine wave circuit configured to determine a value of the cosine wave signal at the current timing by subtracting a multiplication result between a value of the sine wave signal at the previous timing and a value of the filter output signal from a value of the cosine wave signal at the previous timing.

In such a way, a digital sinusoidal wave signal with a high resolution may be generated by simple processing using the predetermined recurrence relations.

In addition, in the present embodiment, the phase comparison circuit may include a counter configured to perform up-count processing or down-count processing based on a result of the phase comparison, and the digital filter may be configured to perform the digital filtering on a counter output signal of the counter.

In such a manner, whether the phase of the digital sinusoidal wave signal is delayed or advanced with respect to the drive clock signal may be determined by the counter performing up-count processing or down-count processing, which enables generation of the digital sinusoidal wave signal phase-locked to the drive clock signal.

In addition, in the present embodiment, the sinusoidal wave generation circuit may be configured to convert a filter output signal of the digital filter to a digital phase signal and generate a digital sinusoidal wave signal based on the digital phase signal.

In such a manner, from a phase comparison result between a drive clock signal and a digital sinusoidal wave signal, a digital phase signal for phase locking to the drive clock signal is determined, and a digital sinusoidal wave signal phase-locked to the drive clock signal based on the determined digital phase signal may be generated.

In addition, in the present embodiment, the phase-locked loop circuit may further include a phase adjustment circuit configured to add a value of a digital phase adjustment signal to a value of the counter output signal.

In such a manner, a digital detection signal and a digital sinusoidal wave signal may be in phase with each other in the mixer, which may reduce degradation in performance caused when the digital detection signal and the digital sinusoidal wave signal are out of phase.

In addition, in the present embodiment, the A/D conversion circuit is a continuous-time ΔΣ A/D conversion circuit.

In such a manner, it is unnecessary to provide an anti-aliasing filter prior to the A/D conversion circuit, which enables a reduction in the circuit area and a decrease in the power consumption of the circuit device to be achieved.

In addition, in the present embodiment, an operating clock frequency of the phase-locked loop circuit and a data output frequency of the A/D conversion circuit may be equal.

This enables the mixer to perform a multiplication between the digital detection signal and the digital sinusoidal wave signal that are input at the same frequency, and thus the mixer may perform an appropriate multiplication to output an output signal.

In addition, a physical quantity detection device in the present embodiment includes the circuit device described above and the physical quantity transducer.

Although the present embodiment has been described above in details, the person skilled in the art would readily understand that many modifications may be made without substantially departing from new matters and effects of the present disclosure. Accordingly, all of such modifications are considered to fall within the scope of the present disclosure. For example, in the specification or the figures, the terms used at least once together with different broader or synonymous terms may be replaced with the different terms in any part of the specification or the figures. In addition, the configurations of the circuit device, the physical quantity detection device, and the physical quantity transducer are not limited to those described in the present embodiment and may be implemented in various modifications.

What is claimed is:

1. A circuit device comprising:
a drive circuit configured to drive a physical quantity transducer;
a phase-locked loop circuit configured to generate a digital sinusoidal wave signal phase-locked to a drive clock signal from the drive circuit;
an analog-to-digital (A/D) conversion circuit configured to perform A/D conversion of a detection signal of the physical quantity transducer; and
a mixer configured to perform a multiplication between the digital detection signal after the A/D conversion and the digital sinusoidal wave signal, wherein
the phase-locked loop circuit is configured to perform a phase comparison between the drive clock signal and the digital sinusoidal wave signal or a digital phase signal of the digital sinusoidal wave signal to generate the digital sinusoidal wave signal phase-locked to the drive clock signal.

2. The circuit device according to claim 1, wherein the phase-locked loop circuit includes
a phase comparison circuit configured to perform the phase comparison between the drive clock signal and the digital sinusoidal wave signal or the digital phase signal;
a digital filter configured to perform digital filtering on a phase comparison result signal of the phase comparison circuit; and
a sinusoidal wave generation circuit configured to output the digital sinusoidal wave signal based on a filter output signal of the digital filter.

3. The circuit device according to claim 2, wherein the phase comparison circuit is configured to sample the digital sinusoidal wave signal at an edge timing of the drive clock signal.

4. The circuit device according to claim 2, wherein the phase-locked loop circuit further includes a phase adjustment circuit configured to add a value of a digital phase adjustment signal to a value of the phase comparison result signal.

5. The circuit device according to claim 2, wherein the sinusoidal wave generation circuit is configured to generate, based on a sine wave signal and a cosine wave signal at a previous timing and the filter output signal, the sine wave signal and the cosine wave signal at a current timing to output the sine wave signal as the digital sinusoidal wave signal.

6. The circuit device according to claim 5, wherein the sinusoidal wave generation circuit is configured to
a sine wave circuit configured to determine a value of the sine wave signal at the current timing by adding a multiplication result between a value of the cosine wave signal at the previous timing and a value of the filter output signal to a value of the sine wave signal at the previous timing, and
a cosine wave circuit configured to determine a value of the cosine wave signal at the current timing by subtracting a multiplication result between the value of the sine wave signal at the previous timing and the value of the filter output signal from the value of the cosine wave signal at the previous timing.

7. The circuit device according to claim 2, wherein
the phase comparison circuit includes a counter configured to perform up-count processing or down-count processing based on a result of the phase comparison, and
the digital filter is configured to perform the digital filtering on a counter output signal of the counter.

8. The circuit device according to claim 7, wherein the sinusoidal wave generation circuit is configured to convert the filter output signal of the digital filter to the digital phase signal and to generate the digital sinusoidal wave signal based on the digital phase signal.

9. The circuit device according to claim 7, wherein the phase-locked loop circuit further includes a phase adjustment circuit configured to add a value of a digital phase adjustment signal to a value of the counter output signal.

10. The circuit device according to claim 1, wherein the A/D conversion circuit is a continuous-time delta-sigma A/D conversion circuit.

11. The circuit device according to claim 1, wherein an operating clock frequency of the phase-locked loop circuit and a data output frequency of the A/D conversion circuit are equal.

12. A physical quantity detection device comprising:
the circuit device according to claim 1; and
the physical quantity transducer.
